(19) United States
(12) Patent Application Publication
(10) Pub. No.: US 2013/0052809 A1
(43) Pub. Date: Feb. 28, 2013

(54) PRE-CLEAN METHOD FOR EPITAXIAL DEPOSITION AND APPLICATIONS THEREOF

(71) Applicant: Yu-Cheng TUNG, Kaohsiung City (TW)

(72) Inventor: Yu-Cheng TUNG, Kaohsiung City (TW)

(73) Assignee: UNITED MICROELECTRONICS CORPORATION, Hsinchu (TW)

(21) Appl. No.: 13/217,368

(22) Filed: Aug. 25, 2011

(51) Int. Cl. H01L 21/20

(52) U.S. Cl. 438/503; 257/E21.09

(57) ABSTRACT

A method for fabricating an epitaxizl structure is provided, wherein the method comprises steps as follows: a reactive gas containing nitrogen and fluorine atoms is firstly applied to react with an oxygen-atom-containing residue residing on a surface of a substrate so as to form a solid compound on the surface. Subsequently, an anneal process is performed to sublimate the solid compound. A semiconductor deposition process is then performed on the substrate.

### FIELD OF THE INVENTION

The present invention relates to a method for fabricating a semiconductor device, more particularly to a pre-clean method for epitaxial deposition and the applications thereof.

### BACKGROUND OF THE INVENTION

Epitaxial Deposition, such as a silicon epitaxial deposition process, is one of the many important processes for fabricating a semiconductor device. As semiconductor dimensions continue to shrink and device densities increase, providing the epitaxial deposition process an ideal starting surface with good surface characteristics, such as providing a starting surface without any oxide or silicon-oxycarbide residents or contaminations, has become increasingly important.

Current epitaxial deposition process requires a pre-clean process to remove surface defects or contaminations residing on the starting surface of a semiconductor substrate targeted for deposition. The conventional pre-clean process generally uses either an aqueous solution of hydrogen fluoride (HF), or a gas phase HF to remove the surface defects or contaminations. The aqueous HF solution approach typically requires an additional hydrogen bake at a temperature about 800° C. for several minutes to provide the best possible surface for the subsequent deposition. However, the high baking temperature may damage the starting surface and cause the ion dopants initially doped in the substrate further diffused, thus the dapant profile may be deformed and adversely affects the feature size and the performance of the device.

Furthermore, when the epitaxial deposition is applied for fabricating raised source/drain structure, the HF solution will produce a spacer undercut and result in leakage current between source, drain and gate. As to the gas phase HF approach, a completely gas phase HF oxide removal process to eliminate the hydrogen bake step have shown only limited success, even though the aforementioned drawbacks can be avoided.

Therefore, it is necessary to provide an improved pre-clean method for epitaxial deposition to obviate the drawbacks and problems encountered from the prior art.

### SUMMARY OF THE INVENTION

One aspect of the present invention is to provide a method for fabricating an epitaxial structure, wherein the method comprises steps as follows: Firstly a pre-clean process is performed on a surface of a substrate, wherein the pre-clean process comprising steps of applying a reactive gas containing nitrogen and fluorine atoms to react with an oxygen-atom-containing residue residing on the surface of the substrate so as to form a solid compound on the surface and performing an anneal process to sublimate the solid compound. Subsequently, a semiconductor deposition process is performed on the substrate.

In one embodiment of the present invention, the reactive gas containing nitrogen and fluorine atoms comprises NH₃ gas and gas-phase NF₃. In one embodiment of the present invention, the oxygen-atom-containing residue comprises silicon oxide. In one embodiment of the present invention, the solid compound is formed at room temperature or a temperature about 30° C. In one embodiment of the present invention, the anneal process is performed at a temperature substantially greater than 100° C. In one embodiment of the present invention, the substrate is a silicon substrate.

In one embodiment of the present invention, the semiconductor deposition process may be a physical vapor deposition (PVD) process or a chemical vapor deposition (CVD) process. In one embodiment of the present invention, the semiconductor deposition process can form a SiGe layer, a SiC layer or a SiGeC layer on the surface of the substrate. In one embodiment of the present invention, the pre-clean process is performed in-situ or without vacuum release.

In one embodiment of the present invention, In one embodiment of the present invention, before the reactive gas containing nitrogen and fluorine atoms is applied to react with the oxygen-atom-containing, the method further comprises steps of warming up the surface of the substrate and ionizing the reactive gas containing nitrogen and fluorine atoms in to a reacting plasma.

In accordance with the aforementioned embodiments of the present invention, a pre-clean method applying NH₃ gas and gas-phase NF₃ for removing oxygen containing residue residing on a targeted surface of a substrate prior an epitaxizl deposition process is provided to substitute a prior approach which applying either aqueous or gas phase HF. Because the pre-clean method of the present invention neither apply HF in contact with the substrate nor require high temperature hydrogen baking step, the problems of spacer undercut and current leakage between source, drain and gate may be avoided. In addition, since the pre-clean process can be carried out in-situ or without vacuum release, thus the time interval and manufacture cost of the device fabrication process can be significantly reduced. Therefore, the drawbacks and problems encountered from the prior art can be solved.

### BRIEF DESCRIPTION OF THE DRAWINGS

The above objects and advantages of the present invention will become more readily apparent to those ordinarily skilled in the art after reviewing the following detailed description and accompanying drawings, in which:

FIGS. 1A to 1C are cross sectional views illustrating the method for fabricating a transistor with a SiGe epitaxial structure in accordance with one embodiment of the present invention.

FIG. 2 illustrates a top view partially illustrating a multi-chamber processing system used to fabricate the transistor depicted in FIGS. 1A to 1C.

FIGS. 3A to 3C are schematic views illustrating the apparatus and the steps used to perform the pre-clean process in accordance with one embodiment of the present invention.

### DETAILED DESCRIPTION OF PREFERRED EMBODIMENTS

One of the objects of the present invention is to provide a pre-clean method for epiaxial deposition to deal with the problems of spacer undercut and current leakage between source, drain and gate encountered from the prior art. A transistor 100 with a SiGe epitaxial structure will now be described as a preferred embodiment to more distinguish the objects, the advantages and the use of the present invention.

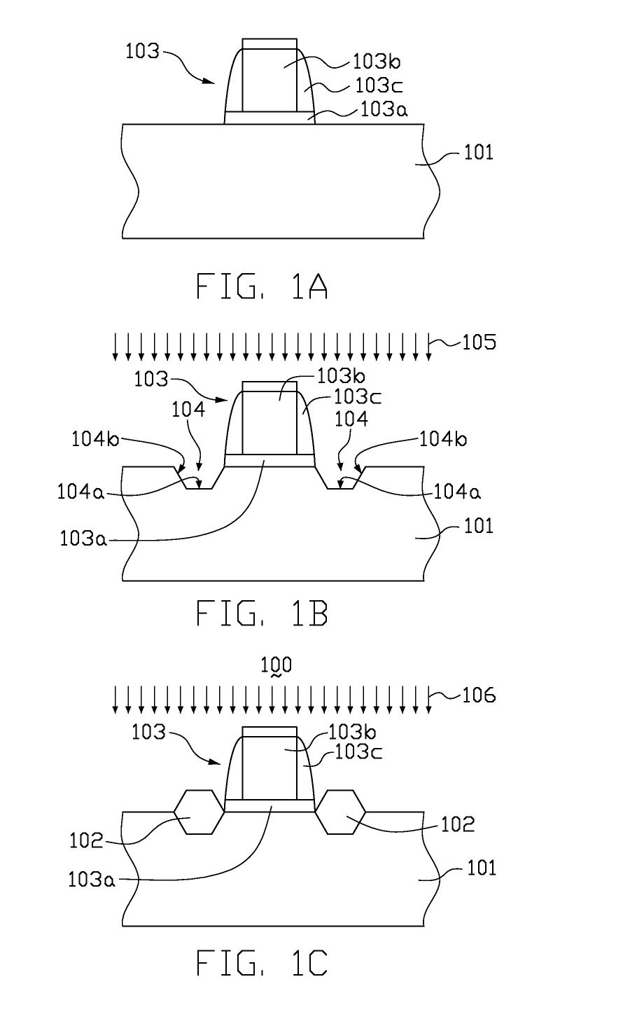

FIGS. 1A to 1C are cross sectional views illustrating the method for fabricating a transistor 100 with a SiGe epitaxial structure in accordance with one embodiment of the present invention. In the present embodiment, the transistor 100 comprises a SiGe source/drain 102 formed by a SiGe epitaxial deposition process and a plurality of ion implantation process performed in a silicon substrate 101. It is to be noted that the following descriptions of the preferred embodiments of this invention are presented herein for purpose of illustration and description only. It is not intended to be exhaustive or to be limited to the precise form disclosed. Therefore, the pre-clean method for epitaxial deposition of the present invention is also applicable to any epitaxial structure with the materials other than SiGe, such as a SiC layer, a SiGeC layer or the like.

The method for fabricating the transistor 100 comprises the following steps: A gate 103 comprising a gate dielectric layer 103a, a gate electrode 103b and space 103c is firstly formed on a surface 101a of the silicon substrate 101 (see FIG. 1A). A recess 104 is then formed in the silicon substrate 101 and extends downwards from the surface 101a of the silicon substrate 101. A pre-clean process 105 is then performed on the bottom 104a and the sidewalls 104b of the recess 104 (see FIG. 1B).

Subsequently, a semiconductor deposition process 106 is performed, whereby a SiGe source/drain 102 is formed in the silicon substrate 101, meanwhile the transistor 100 is completed.

In the present embodiment, the semiconductor deposition process 106 comprises the following steps: The silicon substrate 101 is pre-baked at a temperature ranging from 550° C. to 850° C. within an atmosphere having hydrogen gas (H₂). A plurality of selective epitaxial growth process at several directions is performed by using an ultra-vacuum chemical vapor deposition (UVCVD) or a plasma enhanced chemical vapor deposition (PECVD) within an atmosphere having monosilane (SiH₄) and momogermane (GeH₄) to form the SiGe source/drain 102 in the recess 104.

In some embodiments of the present invention, the semiconductor deposition process 106 and the pre-clean process 105 are performed in the same chamber. In some other embodiments, these two processes are carried out in two different chambers involved in the same apparatus without vacuum release.

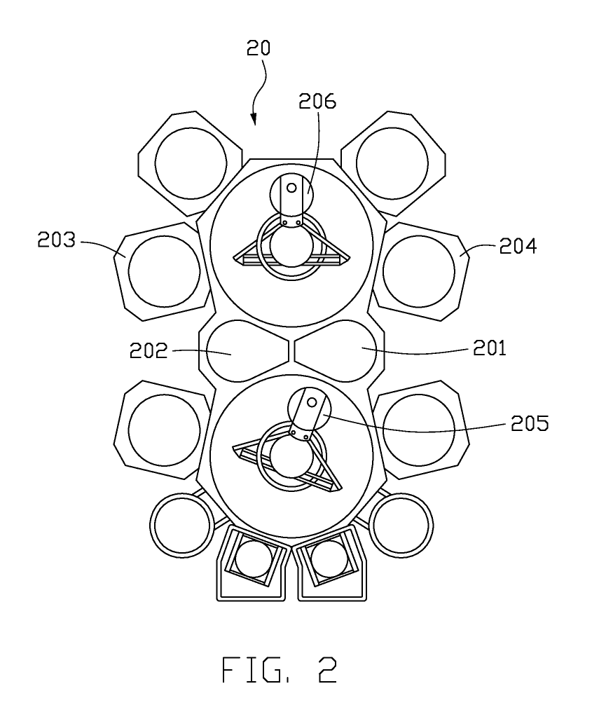

FIG. 2 illustrates a top view partially illustrating a multi-chamber processing system 20 used to fabricate the transistor 100 depicted in FIGS. 1A to 1C. The multi-chamber processing system 20 comprises a plurality of chambers with various functions. For example, the multi-chamber processing system 20 comprises some chambers 201 and 202 used for performing etching processes and chambers used to perform other process, such as sputtering/deposition chambers 203 and 204.

During the fabrication process, the multi-chamber processing system 20 may be sealed up and kept with a certain degree of vacuum, and the silicon substrate 101 (preferably is a silicon wafer) can be transferred form one chamber to another by the robots 205 and 206 in order to perform different processes. Accordingly, the semiconductor deposition process 106 and the pre-clean process 105 can either performed in-situ at the same chamber or performed at different chambers with out vacuum release. Since the multi-chamber processing system 20 have bee well known by those skilled in the art, thus the structure, mechanism and the operation of the multi-chamber processing system 20 will not be redundantly described.

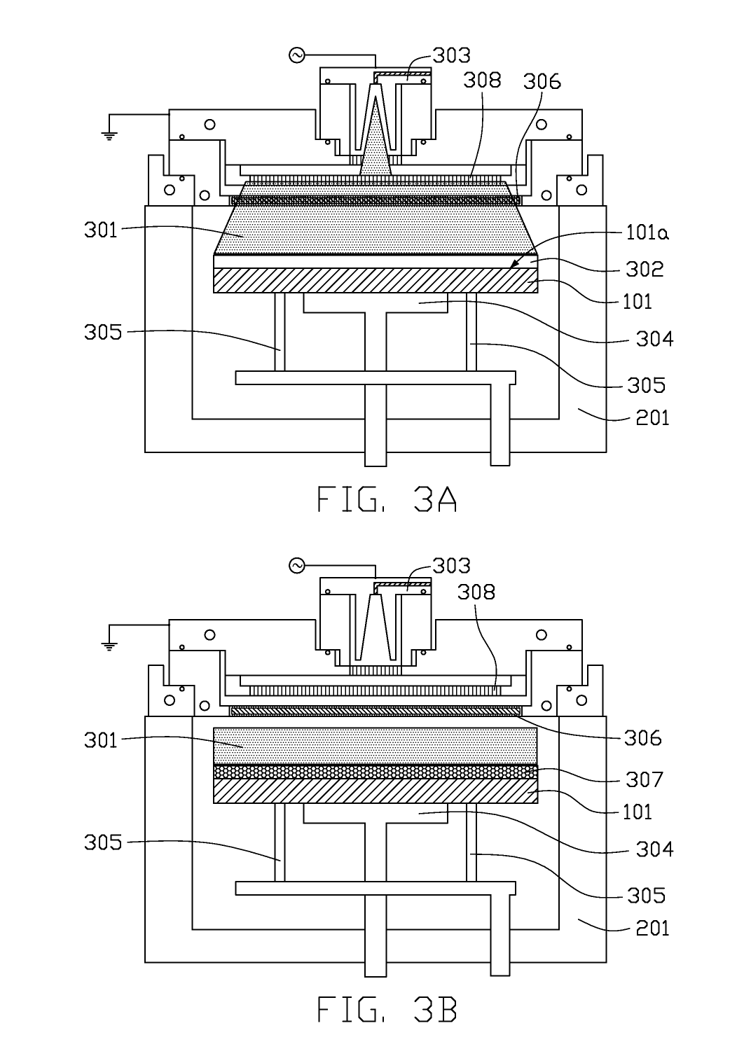

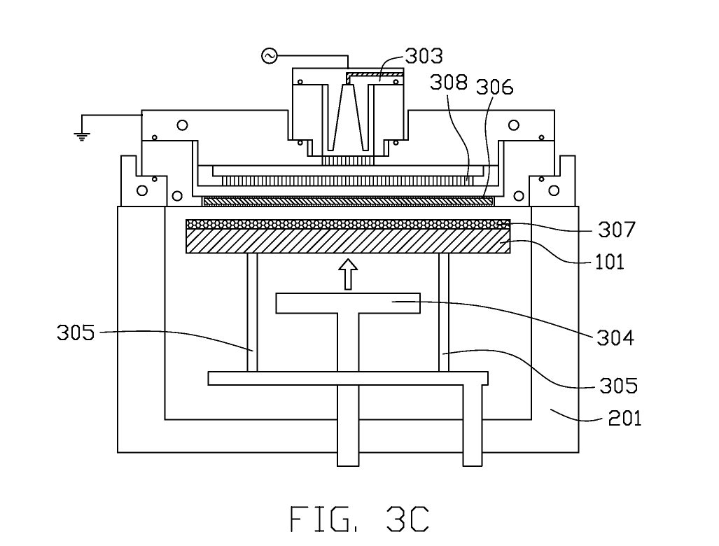

FIGS. 3A to 3C are schematic views illustrating the apparatus and the steps used to perform the pre-clean process 105 in accordance with one embodiment of the present invention. In the present embodiment, the pre-clean process is a dry cleaning process carried out in the same chamber.

The pre-clean process 105 comprises steps as follows: The silicon substrate 101 is firstly disposed in the chamber 201, and a reactive gas containing nitrogen and fluorine atoms is then ionized by a remote plasma source to form a reacting plasma 301 and is subsequently directed into the chamber 201 in contact with the surface 101a of the silicon substrate 101. In the present embodiment, the reactive gas comprises NH₃ gas and gas-phase NF₃.

As shown in FIG. 3A, the silicon substrate 101 is disposed on the operation base 304 with a consist temperature as room temperature or about 30° C. or is warm up by driving the surface 101a of the silicon substrate 101 getting close to the heater 306, wherein the temperature of the surface 101a is preferably controlled at 35° C. The reacting plasma 301 is generated by ionizing the mixed gas consisting of NH₃ gas and gas-phase NF₃. In the present embodiment, the reacting plasma 301 is introduced into the chamber 201 by a plasma nozzle 303 with a high voltage and then dispersed onto the surface 101a of the silicon substrate 101 by a gas palte 308 in order to etch the surface 101 a of the silicon substrate 101.

As expressed in the chemical equation 1, the mixed gas introduced into the chamber 201 by the plasma nozzle 303 may be ionized to form NH₄F and NH₄F.HF plasma.

NF₃+NH₃→NH₄F+NH₄F.HF (Equation 1)

The NH₄F and NH₄F.HF plasma may react with the oxygen-atom-containing residue 302 residing on surface 101a of the silicon substrate 101 to form a solid compound 307. In the present embodiment, the solid compound 307 is ((NH₄)₂SiF₆) and the chemical reaction is set forth in the following chemical equation 2:

NH₄F+NH₄F.HF+SiO₂→(NH₄)₂SiF_{6(SOLID)}+H₂ (Equation 2)

Because this kind of solid compound 307 can be sublimated at a temperature substantially greater than 70° C. Thus the solid compound 307 can be removed by performing an anneal process with a temperature about 100° C. In the present embodiment, an in-situ anneal process is conducted to remove the solid compound 307 from the surface 101a of the silicon substrate 101. As shown in FIG. 3C, the silicon substrate 101 is optionally lifted by a lift pins 305, such that the surface 101a of the silicon substrate 101 can be driven to getting close to the heater 306, whereby the temperature of the surface 101a can be incresed by more than 100° C. rapidly, and the solid compound 307 can be removed from the surface 101a of the silicon substrate 101 by an air pump (not shown) without transferring the silicon substrate 101. The chemical reaction of the solid compound 307 sublimation is set forth in the following chemical equation 3:

(NH₄)₂SiF_{6(SOLID)}→SiF_{4(g)}+NH_{3(g)} (Equation 3)

Because the pre-clean process 105 is a dry etching process used to remove the residues residing on the surface 101a of the silicon substrate 101 by using a plasma consisting of NH₃ and NF₃ serves as the etchant, neither aqueous HF or gas phase HF is required. In addition, the anneal temperature of the pre-clean process 105 is more less than that of the hydrogen bake process following the conventional HF approaches. Thus the problems of spacer undercut and current leakage between source, drain and gate encountered from the prior art may be avoided. In other words, the pre-clean process 105 of the present invention can achieve the functions previously provided by the conventional HF approach without adversely affect the device feature size and performance.

In accordance with the aforementioned embodiments of the present invention, a pre-clean method applying NH₃ gas and gas-phase NF₃ for removing oxygen containing residue residing on a targeted surface of a substrate prior an epitaxizl deposition process is provided to substitute a prior approach which applying either aqueous or gas phase HF. Because the pre-clean method of the present invention neither apply HF in contact with the substrate nor require high temperature hydrogen baking step, the problems of spacer undercut and current leakage between source, drain and gate may be avoided. In addition, since the pre-clean process can be carried out in-situ or without vacuum release, thus the time interval and manufacture cost of the device fabrication process can be significantly reduced. Therefore, the drawbacks and problems encountered from the prior art can be solved.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method for fabricating an epitaxial structure comprising:
applying a reactive gas containing nitrogen and fluorine atoms to react with an oxygen-atom-containing residue residing on a surface of a substrate so as to form a solid compound on the surface;
performing an anneal process to sublimate the solid compound; and
performing a semiconductor deposition process on the substrate.

2. The method for fabricating an epitaxial structure according to claim 1, wherein the reactive gas comprises NH₃ gas and gas-phase NF₃.

3. The method for fabricating an epitaxial structure according to claim 1, wherein the oxygen-atom-containing residue comprises silicon oxide.

4. The method for fabricating an epitaxial structure according to claim 1, wherein the solid compound is formed at room temperature or a temperature about 30° C.

5. method for fabricating an epitaxial structure according to claim 1, wherein the anneal process is performed at a temperature substantially greater than 100° C.

6. The method for fabricating an epitaxial structure according to claim 1, wherein the substrate is a silicon substrate.

7. The method for fabricating an epitaxial structure according to claim 1, wherein the semiconductor deposition process is a physical vapor deposition (PVD) process or a chemical vapor deposition (CVD) process.

8. The method for fabricating an epitaxial structure according to claim 1, wherein the semiconductor deposition process can form a SiGe layer, a SiC layer or a SiGeC layer on the surface of the substrate.

9. The method for fabricating an epitaxial structure according to claim 1, wherein the pre-clean process is performed in-situ or without vacuum release.

10. The method for fabricating an epitaxial structure according to claim 1, wherein before the reactive gas containing nitrogen and fluorine atoms is applied to react with the oxygen-atom-containing, the method further comprises:
warming up the surface of the substrate; and
ionizing the reactive gas containing nitrogen and fluorine atoms in to a reacting plasma.
